(19) United States
(12) Patent Application Publication
(10) Pub. No.: US 2025/0374797 A1
(43) Pub. Date: Dec. 4, 2025

(54) DISPLAY DEVICE AND MANUFACTURING METHOD OF THE SAME

(71) Applicant: Japan Display Inc., Tokyo (JP)

(72) Inventor: Kaichi FUKUDA, Tokyo (JP)

(73) Assignee: Japan Display Inc., Tokyo (JP)

(21) Appl. No.: 19/218,883

(22) Filed: May 27, 2025

(30) Foreign Application Priority Data
May 29, 2024 (JP) 2024-087137

(51) Int. Cl. H10K 59/80; H10K 59/12; H10K 102/00

(52) U.S. Cl. CPC H10K 59/80518; H10K 59/1201; H10K 2102/351

(57) ABSTRACT

According to one embodiment, a display device includes an organic insulating layer formed of an organic insulating material, a lower electrode provided above the organic insulating layer, a coating resin layer covering at least part of an end portion of the lower electrode, a rib layer covering the end portion of the lower electrode and the coating resin layer, and including a pixel aperture which overlaps with the lower electrode, an organic layer covering the lower electrode through the pixel aperture and emitting light in accordance with application of a voltage, and an upper electrode covering the organic layer.

### CROSS-REFERENCE TO RELATED APPLICATIONS

This application is based upon and claims the benefit of priority from Japanese Patent Application No. 2024-087137, filed May 29, 2024, the entire contents of which are incorporated herein by reference.

### FIELD

Embodiments described herein relate generally to a display device and a manufacturing method of the same.

### BACKGROUND

Recently, display devices to which an organic light emitting diode (OLED) is applied as a display element have been put into practical use. In this type of display devices, a technique which can improve the yield is required.

### BRIEF DESCRIPTION OF THE DRAWINGS

FIG. 1 is a diagram showing a configuration example of a display device according to a first embodiment.

FIG. 2 is a schematic plan view showing an example of a layout of subpixels according to the first embodiment.

FIG. 3 is a schematic cross-sectional view showing the display device along the III-III line of FIG. 2.

FIG. 4 is a schematic cross-sectional view showing the display device along the IV-IV line of FIG. 2.

FIG. 5 is a schematic cross-sectional view showing another configuration which can be applied to a lower electrode and a coating resin layer.

FIG. 6 is a flowchart showing an example of a manufacturing method of the display device according to the first embodiment.

FIG. 7A is a schematic cross-sectional view showing the manufacturing process of the display device.

FIG. 7B is a schematic cross-sectional view showing a process following FIG. 7A.

FIG. 7C is a schematic cross-sectional view showing a process following FIG. 7B.

FIG. 7D is a schematic cross-sectional view showing a process following FIG. 7C.

FIG. 7E is a schematic cross-sectional view showing a process following FIG. 7D.

FIG. 7F is a schematic cross-sectional view showing a process following FIG. 7E.

FIG. 7G is a schematic cross-sectional view showing a process following FIG. 7F.

FIG. 7H is a schematic cross-sectional view showing a process following FIG. 7G.

FIG. 7I is a schematic cross-sectional view showing a process following FIG. 7H.

FIG. 7J is a schematic cross-sectional view showing a process following FIG. 7I.

FIG. 8A is a schematic cross-sectional view showing a process following FIG. 7J.

FIG. 8B is a schematic cross-sectional view showing a process following FIG. 8A.

FIG. 8C is a schematic cross-sectional view showing a process following FIG. 8B.

FIG. 8D is a schematic cross-sectional view showing a process following FIG. 8C.

FIG. 8E is a schematic cross-sectional view showing a process following FIG. 8D.

FIG. 8F is a schematic cross-sectional view showing a process following FIG. 8E.

FIG. 9 is a schematic cross-sectional view showing the structure of the vicinity of an end portion of a lower electrode according to a comparative example of the embodiment.

FIG. 10 is a schematic plan view showing an example of a layout of subpixels according to a second embodiment.

FIG. 11 is a schematic cross-sectional view showing the display device along the XI-XI line of FIG. 10.

### DETAILED DESCRIPTION

In general, according to one embodiment, there is provided a display device comprising: an organic insulating layer formed of an organic insulating material; a lower electrode provided above the organic insulating layer; a coating resin layer covering at least part of an end portion of the lower electrode; a rib layer covering the end portion of the lower electrode and the coating resin layer, and including a pixel aperture which overlaps with the lower electrode; an organic layer covering the lower electrode through the pixel aperture and emitting light in accordance with application of a voltage; and an upper electrode covering the organic layer.

According to another embodiment, there is provided a display device manufacturing method comprising: forming an organic insulating layer of an organic insulating material; forming a lower electrode and a coating resin layer covering at least part of an end portion of the lower electrode, above the organic insulating layer; forming a rib layer covering the end portion of the lower electrode and the coating resin layer, and including a pixel aperture which overlaps with the lower electrode; forming an organic layer covering the lower electrode through the pixel aperture and emitting light in accordance with application of a voltage; and forming an upper electrode covering the organic layer.

According to the configuration of the display device and the display device manufacturing method, the yield of the display device can be improved.

Several embodiments will be described hereinafter with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown as needed. A direction parallel to the X-axis is referred to as an X-direction. A direction parallel to the Y-axis is referred to as a Y-direction. A direction parallel to the Z-axis is referred to as a Z-direction. The Z-direction is a direction of a normal of a plane including the X-direction and the Y-direction. In addition, when various elements are viewed parallel to the Z-direction, the appearance is defined as plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

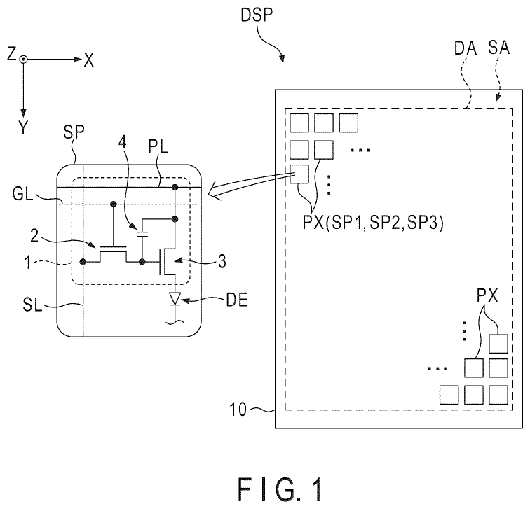

FIG. 1 is a diagram showing a configuration example of a display device DSP according to a first embodiment. The display device DSP comprises an insulating substrate 10. The substrate 10 has a display area DA where an image is displayed, and a surrounding area SA around the display area DA. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in the X-direction and the Y-direction. Each pixel PX includes a plurality of subpixels SP which display different colors. In the present embodiment, it is assumed that the pixel PX includes a blue subpixel SP1 (first subpixel), a green subpixel SP2 (second subpixel), and a red subpixel SP3 (third subpixel). However, the pixel PX may include a subpixel SP which exhibits the other color such as white in addition to the subpixels SP1, SP2 and SP3 or instead of one of the subpixels SP1, SP2 and SP3.

The subpixel SP comprises a pixel circuit 1 and a display element DE driven by the pixel circuit 1. The pixel circuit 1 comprises a pixel switch 2, a drive transistor 3, and a capacitor 4. Each of the pixel switch 2 and the drive transistor 3 is, for example, a switching element which consists of a thin-film transistor.

A plurality of scanning lines GL that supply a scanning signal to the pixel circuit 1 of each subpixel SP, a plurality of signal lines SL that supply a video signal to the pixel circuit 1 of each subpixel SP, and a plurality of power lines PL are provided in the display area DA. In the example of FIG. 1, the scanning lines GL and the power lines PL extend in the X-direction, and the signal lines SL extend in the Y-direction.

The gate electrode of the pixel switch 2 is connected to the scanning line GL. The source electrode of the pixel switch 2 is connected to the signal line SL. The drain electrode of the pixel switch 2 is connected to the gate electrode of the drive transistor 3 and the capacitor 4. The source electrode of the drive transistor 3 is connected to the power line PL and the capacitor 4. The drain electrode of the drive transistor 3 is connected to the display element DE.

It should be noted that the configuration of the pixel circuit 1 is not limited to the example shown in the figure. For example, the pixel circuit 1 may comprise more thin-film transistors and capacitors.

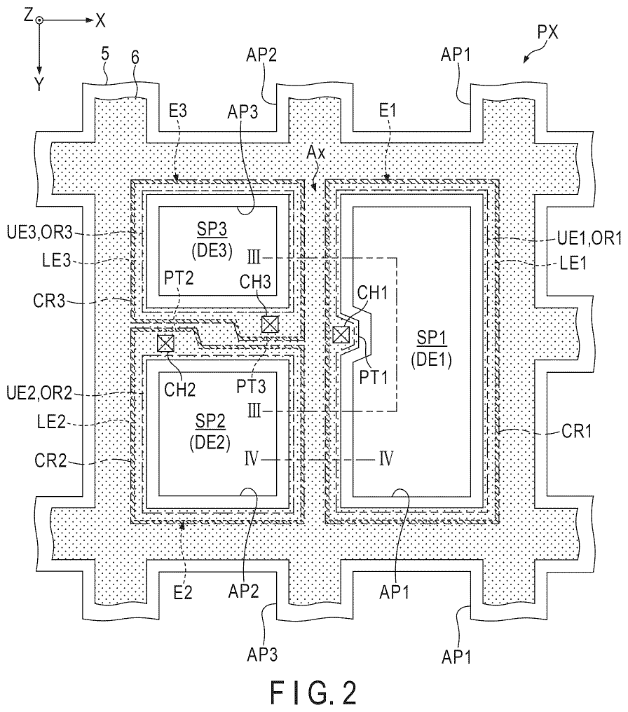

FIG. 2 is a schematic plan view showing an example of the layout of subpixels SP1, SP2 and SP3. In the example of FIG. 2, each of subpixels SP2 and SP3 is adjacent to subpixel SP1 in the X-direction. Further, subpixels SP2 and SP3 are arranged in the Y-direction.

When subpixels SP1, SP2 and SP3 are provided in line with this layout, in the display area DA, a column in which subpixels SP2 and SP3 are alternately provided in the Y-direction and a column in which a plurality of subpixels SP1 are repeatedly provided in the Y-direction are formed. These columns are alternately arranged in the X-direction. It should be noted that the layout of subpixels SP1, SP2 and SP3 is not limited to the example of FIG. 2.

A rib layer 5 is provided in the display area DA. The rib layer 5 has pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3. Thus, among subpixels SP1, SP2 and SP3, the aperture ratio of subpixel SP1 is the greatest, and the aperture ratio of subpixel SP3 is the least. It should be noted that the size of the pixel aperture AP1, AP2 or AP3 is not limited to this example. For example, at least two of the pixel apertures AP1, AP2 and AP3 may have the same size.

The subpixel SP1 comprises a lower electrode LE1, an upper electrode UE1 and an organic layer OR1 overlapping with the pixel aperture AP1. The subpixel SP2 comprises a lower electrode LE2, an upper electrode UE2 and an organic layer OR2 overlapping with the pixel aperture AP2. The subpixel SP3 comprises a lower electrode LE3, an upper electrode UE3 and an organic layer OR3 overlapping with the pixel aperture AP3.

Of the lower electrode LE1, the upper electrode UE1 and the organic layer OR1, the portions which overlap the pixel aperture AP1 constitute the display element DE1 of the subpixel SP1. Of the lower electrode LE2, the upper electrode UE2 and the organic layer OR2, the portions which overlap the pixel aperture AP2 constitute the display element DE2 of the subpixel SP2. Of the lower electrode LE3, the upper electrode UE3 and the organic layer OR3, the portions which overlap the pixel aperture AP3 constitute the display element DE3 of the subpixel SP3. Each of the display elements DE1, DE2 and DE3 may further include a cap layer as described later. The rib layer 5 surrounds each of these display elements DE1, DE2 and DE3.

A partition 6 is provided in the display area DA. The partition 6 is located above the rib layer 5 and overlaps the rib layer 5 as a whole. In the example of FIG. 2, the partition 6 has a planar shape similar to that of the rib layer 5. In other words, the partition 6 has an aperture in each of subpixels SP1, SP2 and SP3. From another viewpoint, each of the rib layer 5 and the partition 6 has a grating shape as seen in plan view, and surrounds each of the display elements DE1, DE2 and DE3. The partition 6 functions as lines which apply common voltage to the upper electrodes UE1, UE2 and UE3.

The lower electrodes LE1, LE2 and LE3 are connected to the pixel circuits 1 (more specifically, the drain electrodes of the drive transistors 3 shown in FIG. 1) of the subpixels SP1, SP2 and SP3 through contact holes CH1, CH2 and CH3 provided in an organic insulating layer 12 to be described later, respectively. Each of the contact holes CH1, CH2 and CH3 overlaps with the rib layer 5 and the partition 6.

In the example of FIG. 2, the partition 6 has a protrusion PT1 which protrudes toward the pixel aperture AP1. The contact hole CH1 overlaps with the protrusion PT1. In addition, the lower electrode LE2 has a protrusion PT2 which protrudes toward the lower electrode LE3. Furthermore, the lower electrode LE3 has a protrusion PT3 which protrudes toward the lower electrode LE2. The contact holes CH2 and CH3 overlap with these protrusions PT2 and PT3, respectively.

The subpixels SP1, SP2 and SP3 comprise coating resin layers CR1, CR2 and CR3, respectively. In FIG. 2, a diagonal pattern is added to the coating resin layers CR1, CR2 and CR3.

The coating resin layer CR1 is provided along the end portion E1 of the lower electrode LE1 and surrounds the lower electrode LE1. The coating resin layer CR2 is provided along the end portion E2 of the lower electrode LE2 and surrounds the lower electrode LE2. The coating resin layer CR3 is provided along the end portion E3 of the lower electrode LE3 and surrounds the lower electrode LE3.

For example, the end portions E1, E2 and E3 of the lower electrodes LE1, LE2 and LE3 and the coating resin layers CR1, CR2 and CR3 overlap with the rib layer 5 and the partition 6 as a whole. It should be noted that part of the end portion E1, E2 or E3 or the coating resin layer CR1, CR2 or CR3 may not overlap with the partition 6.

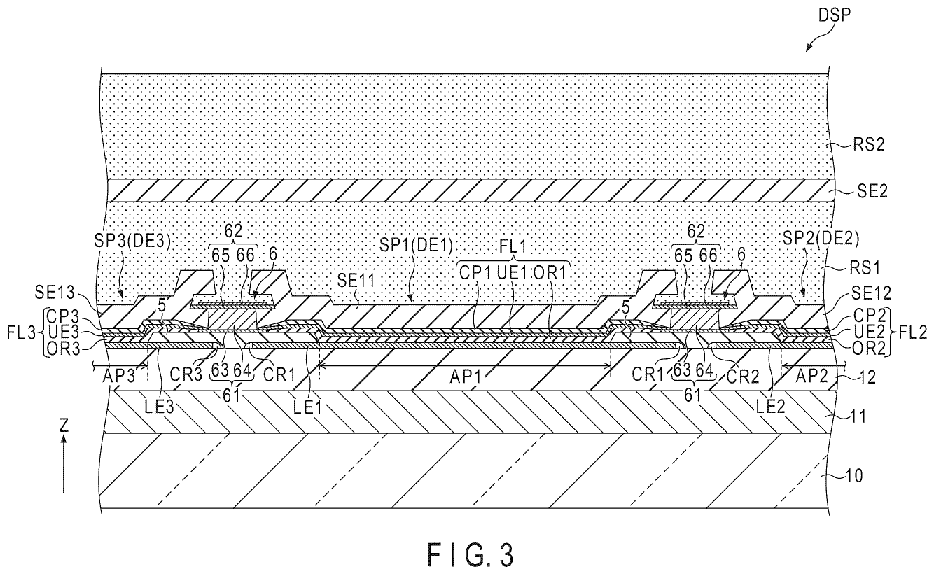

FIG. 3 is a schematic cross-sectional view showing the display device DSP along III-III line in FIG. 2. A circuit layer 11 is provided on the above-described substrate 10. The circuit layer 11 includes various circuits and lines such as the pixel circuit 1, the scanning line GL, the signal line SL, and the power line PL shown in FIG. 1. The circuit layer 11 is covered with an organic insulating layer 12. The organic insulating layer 12 functions as a planarization film which planarizes the irregularities formed by the circuit layer 11.

Each of the lower electrodes LE1, LE2 and LE3 and the coating resin layers CR1, CR2 and CR3 is provided on the organic insulating layer 12. The rib layer 5 is provided on the organic insulating layer 12 and the lower electrodes LE1, LE2 and LE3. All of the end portions (the end portions E1, E2 and E3 shown in FIG. 2) of the lower electrodes LE1, LE2 and LE3 and the coating resin layers CR1, CR2 and CR3 are covered with the rib layer 5.

The partition 6 includes a conductive lower portion 61 provided on the rib layer 5 and an upper portion 62 provided on the lower portion 61. The upper portion 62 has a width greater than that of the lower portion 61. Accordingly, the both end portions of the upper portion 62 protrude relative to the side surfaces of the lower portion 61. In other words, the partition 6 has an overhang shape in which the both end portions of the upper portion 62 protrude relative to the side surfaces of the lower portion 61.

In the example of FIG. 3, the lower portion 61 includes a bottom layer 63 and a stem layer 64. The bottom layer 63 is located between the stem layer 64 and the rib layer 5. Furthermore, in the example of FIG. 3, the upper portion 62 includes a first top layer 65 and a second top layer 66. The first top layer 65 is provided on the stem layer 64. The second top layer 66 is provided on the first top layer 65.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the lower portions 61 of the partition 6.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2 and CP3 play a role of serving as optical adjustment layers which improve the extraction efficiency of the light emitted from the organic layers OR1, OR2 and OR3, respectively.

In the following descriptions, a multilayer body including the organic layer OR1, the upper electrode UE1, and the cap layer CP1 is referred to as a stacked film FL1. A multilayer body including the organic layer OR2, the upper electrode UE2, and the cap layer CP2 is referred to as a stacked film FL2. A multilayer body including the organic layer OR3, the upper electrode UE3, and the cap layer CP3 is referred to as a stacked film FL3.

Sealing layers SE11, SE12, and SE13 which cover the stacked films FL1, FL2, and FL3, are provided in the subpixels SP1, SP2, and SP3, respectively. More specifically, the sealing layer SE11 continuously covers the cap layer CP1 and the partition 6 around the subpixel SP1. The sealing layer SE12 continuously covers the cap layer CP2 and the partition 6 around the subpixel SP2. The sealing layer SE13 continuously covers the cap layer CP3 and the partition 6 around the subpixel SP3.

In the example of FIG. 3, the sealing layer SE11 located on the partition 6 between the subpixels SP1 and SP2 is spaced apart from the sealing layer SE12 located on the partition 6. In addition, the sealing layer SE11 located on the partition 6 between the subpixels SP1 and SP3 is spaced apart from the sealing layer SE13 located on the partition 6. However, two of the sealing layers SE11, SE12, and SE13 may be in contact with each other above the partition 6.

For example, a gap is formed between each of the sealing layers SE11, SE12, and SE13 and the upper portion 62 of the partition 6. The stacked films FL1, FL2, and FL3 may be provided in at least part of these gaps.

The sealing layers SE11, SE12, and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a protective film or a cover glass may be further provided above the resin layer RS2. Such a cover member may be attached to the resin layer RS2 via, for example, an adhesive layer such as an optical clear adhesive (OCA).

The electrodes which constitute the above-described touch panel may be provided on the sealing layer SE2. In addition, color filters corresponding to the colors of the subpixels SP1, SP2, and SP3 may be provided above the display elements DE1, DE2, and DE3, respectively.

The organic insulating layer 12 is formed of an organic insulating material such as polyimide. The rib layer 5 and the sealing layers SE11, SE12, SE13 and SE2 are formed of an inorganic insulating material such as silicon nitride (SiNx), silicon oxide (SiOx) or silicon oxynitride (SiON). In one example, the rib layer 5 is formed of silicon oxynitride, and each of the sealing layers SE11, SE12, SE13 and SE2 is formed of silicon nitride. The resin layers RS1 and RS2 are formed of, for example, a resinous material (organic insulating material) such as epoxy resin or acrylic resin.

The upper electrodes UE1, UE2 and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 consists of a plurality of thin films including a light emitting layer. In one example, each of the organic layers OR1, OR2, and OR3 comprises a structure in which a hole injection layer, a hole transport layer, an electron blocking layer, a light emitting layer, a hole blocking layer, an electron transport layer and an electron injection layer are stacked in order in the Z-direction. However, each of the organic layers OR1, OR2, and OR3 may comprise an alternative structure such as a so-called tandem structure including a plurality of light emitting layers.

Each of the cap layers CP1, CP2, and CP3 comprises, for example, a multilayer structure in which a plurality of transparent layers are stacked. These transparent layers may include a layer formed of an inorganic material and a layer formed of an organic material. In addition, the transparent layers have refractive indices different from each other. For example, the refractive indices of these transparent layers are different from the refractive indices of the upper electrodes UE1, UE2, and UE3 and the refractive indices of the sealing layers SE11, SE12, and SE13. Incidentally, at least one of the cap layers CP1, CP2, and CP3 may be omitted.

A common voltage is applied to the partition 6. This common voltage is applied to each of the upper electrodes UE1, UE2, and UE3 which are in contact with the lower portion 61. Pixel voltages corresponding to the video signals of the signal lines SL are applied to the lower electrodes LE1, LE2, and LE3 through the pixel circuits 1 provided in the subpixels SP1, SP2 and SP3, respectively.

The organic layers OR1, OR2, and OR3 emit light based on the application of voltages. More specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light exhibiting the same color (for example, white). In this case, the display device DSP may comprise color filters which convert the light emitted from the light emitting layers into light exhibiting colors corresponding to the subpixels SP1, SP2, and SP3. In addition, the display device DSP may comprise a layer including a quantum dot which generates light exhibiting colors corresponding to the subpixels SP1, SP2, and SP3 by the excitation caused by the light emitted from the light emitting layers.

The bottom layer 63 and the stem layer 64 are formed of, for example, a metal material. For the metal material of the bottom layer 63, for example, molybdenum (Mo), titanium (Ti), titanium nitride (TiN), a molybdenum-tungsten alloy (MoW) or a molybdenum-niobium alloy (MoNb) can be used. For the metal material of the stem layer 64, for example, aluminum (Al), an aluminum-neodymium alloy (AlNd), an aluminum-yttrium alloy (AlY) or an aluminum-silicon alloy (AlSi) can be used. Incidentally, at least one of the bottom layer 63 and the stem layer 64 may comprise a multilayer structure consisting of a plurality of layers. Alternatively, the stem layer 64 may include a layer formed of an insulating material. Furthermore, the lower portion 61 may comprise a single-layer structure formed of a conductive material.

For example, the first top layer 65 is formed of a metal material, and the second top layer 66 is formed of a transparent conductive oxide. For the metal material of the first top layer 65, for example, titanium, titanium nitride, molybdenum, tungsten, a molybdenum-tungsten alloy or a molybdenum-niobium alloy can be used. For the conductive oxide of the second top layer 66, for example, indium tin oxide (ITO), indium zinc oxide (IZO), or indium gallium zinc oxide (IGZO) may be used. Incidentally, the upper portion 62 may comprise a single-layer structure formed of a specific material. Furthermore, the upper portion 62 may include a layer formed of an insulating material.

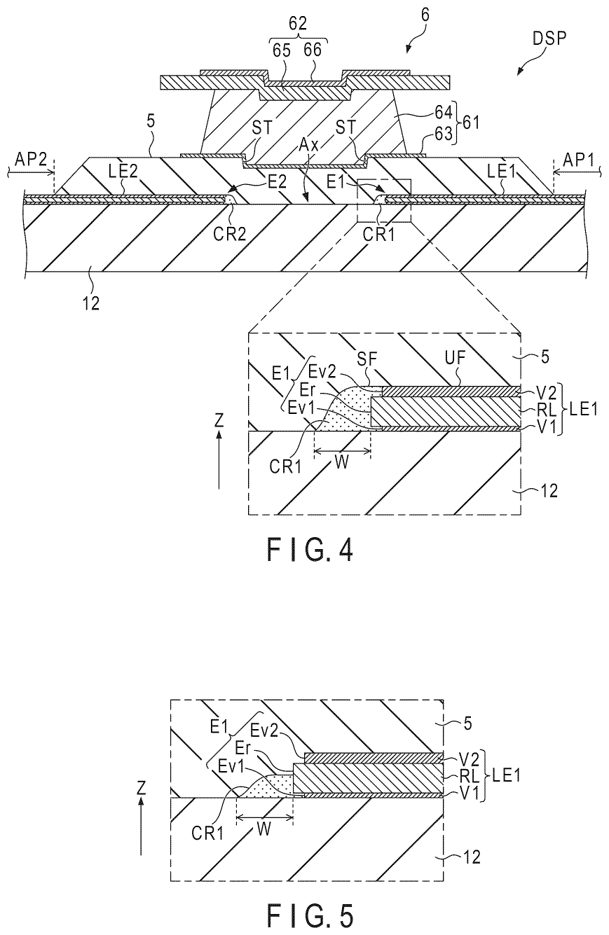

FIG. 4 is a schematic cross-sectional view showing the display device DSP along the IV-IV line in FIG. 2. In this figure, the organic insulating layer 12, the rib layer 5, the partition 6, the lower electrodes LE1 and LE2, and the coating resin layers CR1 and CR2 are shown, and the other elements are omitted.

In the example of FIG. 4, the bottom layer 63 protrudes from the side surfaces of the stem layer 64. In addition, the width of the second top layer 66 is less than that of the first top layer 65. For this reason, the upper surface of the first top layer 65 near the both end portions is exposed from the second top layer 66. The stem layer 64 is formed so as to be thicker than the bottom layer 63, the first top layer 65, and the second top layer 66.

As described above, all of the end portions E1 and E2 of the lower electrodes LE1 and LE2, and the coating resin layers CR1 and CR2 are covered with the rib layer 5. Although not shown in the cross-section of FIG. 4, the end portion E3 of the lower electrode LE3 and the coating resin layer CR3 are also covered with the rib layer 5.

As shown in FIG. 4, the end portions E1 and E2 and the coating resin layers CR1 and CR2 are located under the lower portion 61, more specifically, under the bottom layer 63 and the stem layer 64. Although not shown in the cross-section of FIG. 4, the end portion E3 of the lower electrode LE3 and the coating resin layer CR3 are also located under the bottom layer 63 and the stem layer 64. However, each of the end portions E1, E2, and E3 and the coating resin layers CR1, CR2, and CR3 may have a portion which is not located under the bottom layer 63 or the stem layer 64.

As shown in FIG. 4, stepped portions ST caused by the end portions E1 and E2 are generated on the upper surface of the rib layer 5. Although not shown in the cross-section of FIG. 4, a stepped portion ST caused by the end portion E3 of the lower electrode LE3 is also generated on the upper surface of the rib layer 5. In the present embodiment, these stepped portions ST are covered with the bottom layer 63 and the stem layer 64. The upper surface of each of the stem layer 64, the first top layer 65, and the second top layer 66 may be deformed based on the stepped portions ST.

As shown in the enlarged view of FIG. 4, the lower electrode LE1 includes a reflective layer RL, a first coating layer V1, and a second coating layer V2. The reflective layer RL reflects the light emitted from the organic layer OR1 in the Z-direction. The first coating layer V1 is located between the organic insulating layer 12 and the reflective layer RL and covers the lower surface of the reflective layer RL. The second coating layer V2 covers the upper surface of the reflective layer RL. The first coating layer V1 improves the adherence between the reflective layer RL and the organic insulating layer 12. The second coating layer V2 protects the reflective layer RL from various types of etching at the time of manufacturing the display device DSP.

The reflective layer RL can be formed of, for example, a metal material excellent in light reflectivity, such as silver. Each of the coating layers V1 and V2 can be formed of, for example, a transparent conductive oxide such as ITO, IZO, or IGZO.

In the example of FIG. 4, both the first coating layer V1 and the second coating layer V2 are thinner than the reflective layer RL. In addition, the first coating layer V1 is thinner than the second coating layer V2. For example, the thickness of the reflective layer EL is 40 to 150 nm, and the thickness of each of the first coating layer V1 and the second coating layer V2 is 5 to 50 nm. In addition, the thickness of the rib layer 5 is 200 to 600 nm. However, the thickness of the reflective layer RL, the first coating layer V1, the second coating layer V2, and the rib layer 5 is not limited to the example shown here.

The end portion E1 of the lower electrode LE1 includes an end portion Er of the reflective layer RL, an end portion Ev1 of the first coating layer V1, and an end portion Ev2 of the second coating layer V2. In the example of FIG. 4, the end portion Er protrudes relative to the end portions Ev1 and Ev2.

The coating resin layers CR1, CR2, and CR3 are formed of a resinous material. For the resinous material, for example, a positive photosensitive resin such as photosensitive polyimide or photosensitive acrylic may be used. However, the material is not limited to this example.

In the example of FIG. 4, the coating resin layer CR1 covers the whole part of the end portions Er, Ev1, and Ev2. Space between the organic insulating layer 12 and the end portion Er is filled with the coating resin layer CR1. In addition, the coating resin layer CR1 covers the upper surface of the reflective layer RL, which is exposed from the second coating layer V2.

The coating resin layer CR1 does not cover an upper surface UF of the second coating layer V2. In the example of FIG. 4, the top surface SF of the coating resin layer CR1 is a gently curved surface and is evenly connected with the upper surface UF. As another example, a step may be formed between the top surface SF and the upper surface UF.

Width W of the coating resin layer CR1 is, for example, greater than or equal to the thickness of the reflective layer RL. The width W corresponds to the width of the portion which does not overlap with the reflective layer RL, of the coating resin layer CR1. In one example, the width W is greater than or equal to 0.2 μm, and is desirably 0.5 μm to 1.0 μm.

FIG. 5 is a schematic cross-sectional view showing another configuration which can be applied to the lower electrode LE1 and the coating resin layer CR1. In the example of this figure, part of the end portion E1 of the lower electrode LE1 is covered with the coating resin layer CR1, and the rest of the end portion E1 is not covered with the coating resin layer CR1.

More specifically, in the example of FIG. 5, the end portion Ev1 and the lower portion of the end portion Er are covered with the coating resin layer CR1. Neither the upper portion of the end portion Er nor the end portion Ev2 is covered with the coating resin layer CR1.

Similarly to the lower electrode LE1, each of the lower electrodes LE2 and LE3 comprises the reflective layer RL, the first coating layer V1, and the second coating layer V2. The thicknesses of the reflective layer RL, the first coating layer V1, and the second coating layer V2 in the lower electrodes LE2 and LE3 are equal to the thicknesses of these layers in the lower electrode LE1. The width of each of the coating resin layers CR2 and CR3 is equal to the width W of the coating resin layer CR1. Furthermore, the structure of the vicinity of the end portion E2 of the lower electrode LE2 and the structure of the vicinity of the end portion E3 of the lower electrode LE3 are similar to the structure of the vicinity of the end portion E1 of the lower electrode LE1 shown in FIG. 4 or FIG. 5.

As shown in FIG. 4, the coating resin layers CR1 and CR2 are spaced apart from each other. In an area Ax located between the coating resin layers CR1 and CR2, the organic insulating layer 12 is covered with the rib layer 5. A similar area Ax is also formed between the coating resin layers CR1 and CR3 and between the coating resin layers CR2 and CR3.

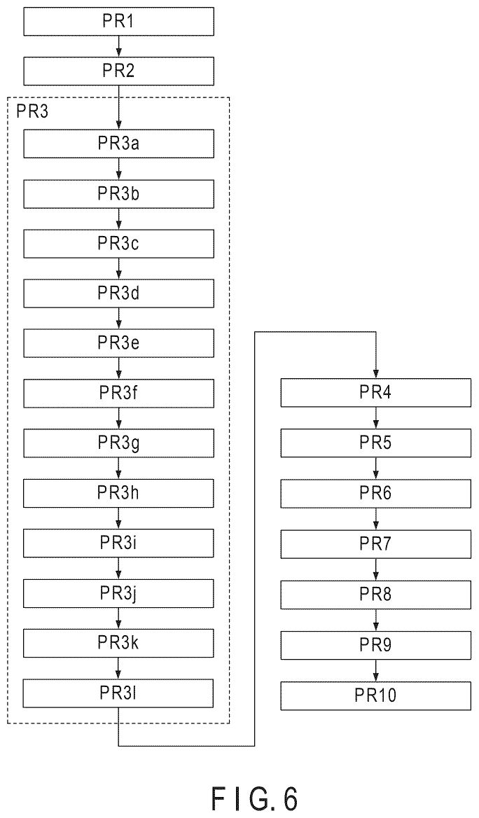

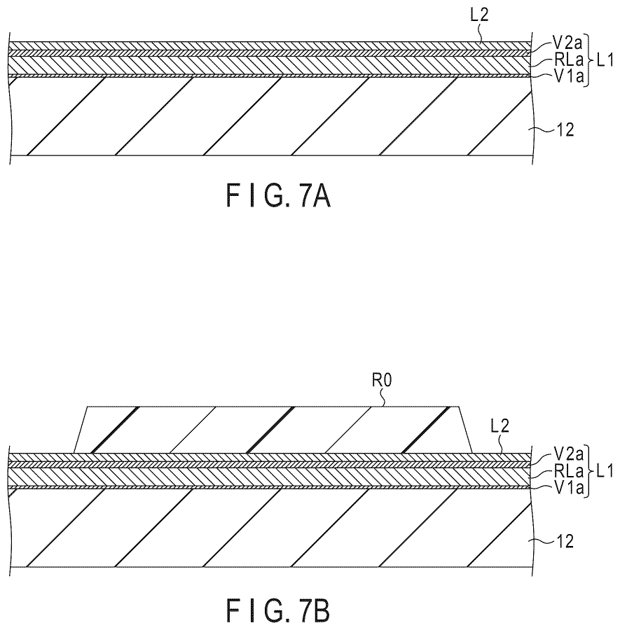

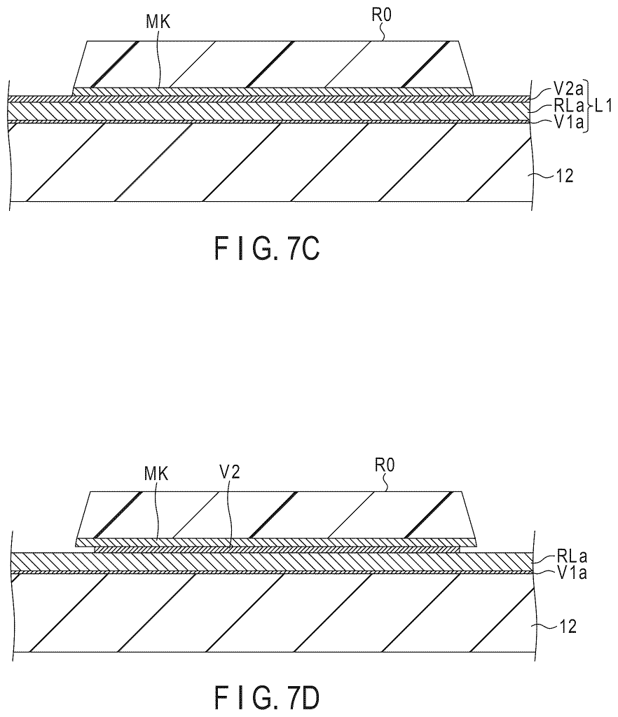

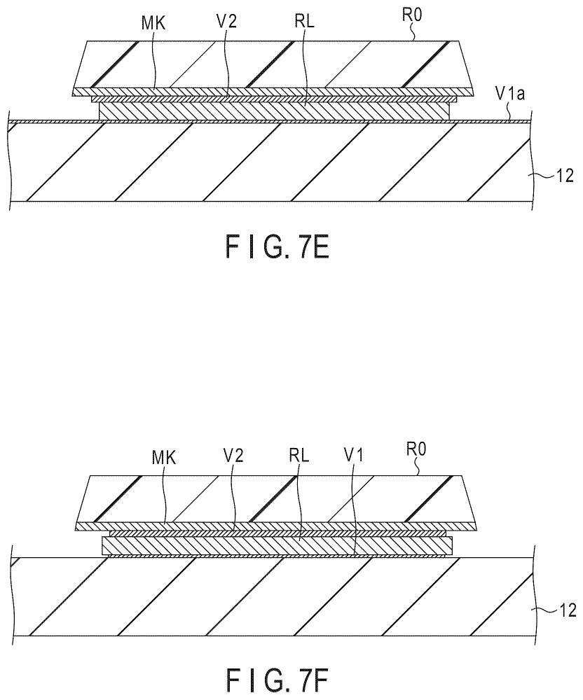

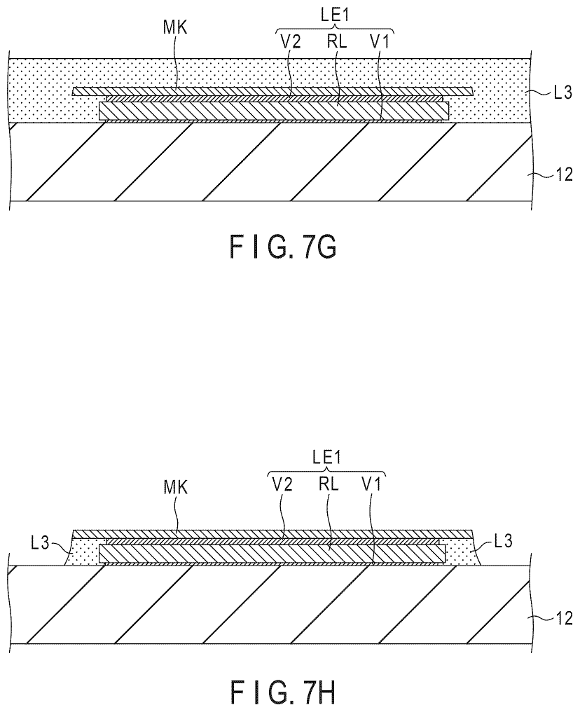

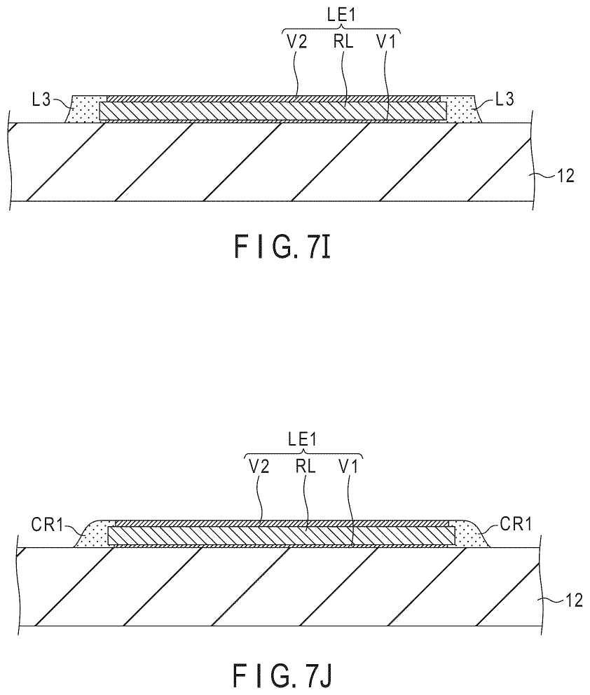

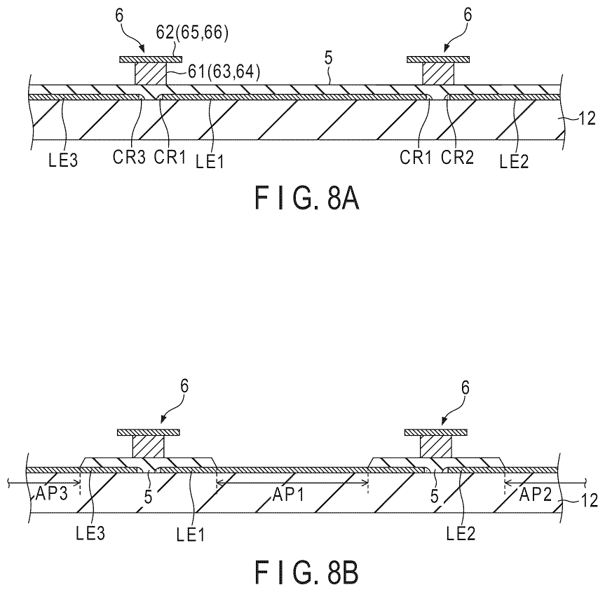

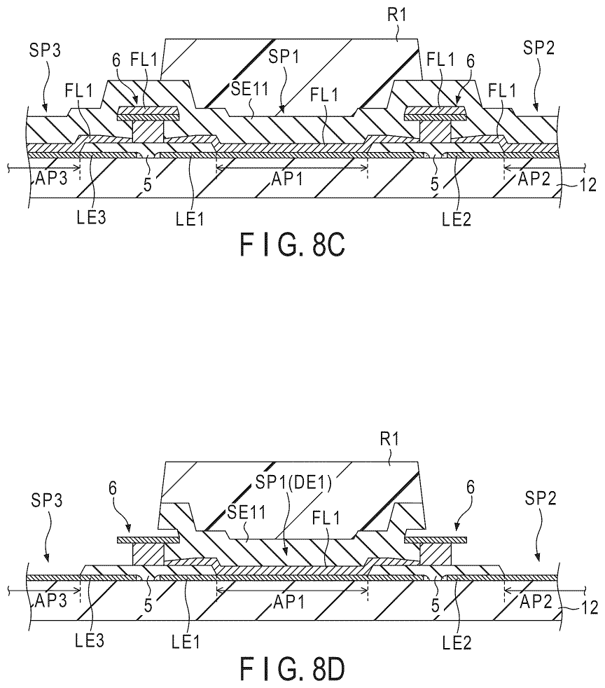

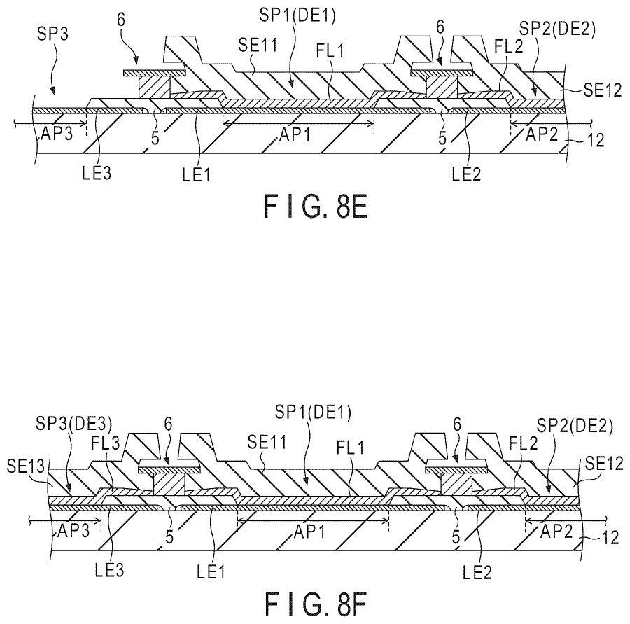

Next, an example of a method of manufacturing the display device DSP will be described. FIG. 6 is a flowchart showing an example of the method of manufacturing the display device DSP. FIG. 7A to FIG. 7J and FIG. 8A to FIG. 8F are schematic cross-sectional views showing manufacturing processes of the display device DSP. In these figures, illustrations of the substrate 10 and the circuit layer 11 are omitted.

To manufacture the display device DSP, first, the circuit layer 11 is formed on the substrate 10 (process PR1 in FIG. 6). Furthermore, the organic insulating layer 12 including the contact holes CH1, CH2, and CH3 is formed on the circuit layer 11 (process PR2 in FIG. 6).

After the process PR2, the lower electrodes LE1, LE2, and LE3 and the coating resin layers CR1, CR2, and CR3 are formed on the organic insulating layer 12 (process PR3 in FIG. 6). For example, when the coating resin layers CR1, CR2, and CR3 are formed of a positive photosensitive resin, the procedure shown in FIG. 7A to FIG. 7J can be applied to process PR3. Incidentally, FIG. 7A to FIG. 7J show a situation in which the lower electrode LE1 and the coating resin layer CR1 are formed. The lower electrodes LE2 and LE3 and the coating resin layers CR2 and CR3 are formed at the same time as the lower electrode LE1 and the coating resin layer CR1.

In the process PR3, first, as shown in FIG. 7A, a first layer L1 formed of the material of the lower electrodes LE1, LE2, and LE3 is formed on the organic insulating layer 12 (process PR3a in FIG. 6). The first layer L1 includes a first coating layer V1a formed of the material of the first coating layer V1, a reflective layer RLa formed of the material of the reflective layer RL, and a second coating layer V2a formed of the material of the second coating layer V2. To form these layers, for example, sputtering may can used.

Subsequently, a second layer L2 is formed on the first layer L1 (process PR3b in FIG. 6). For the material of the second layer L2, various types of metal materials and insulating materials having light-shielding properties for the exposure in process PR3i to be described later can be used. In the present embodiment, an example in which the material of the second layer L2 is titanium will be described. In this case, sputtering can be used for formation of the second layer L2.

The second layer L2 is, for example, thinner than the reflective layer RLa. For example, the thickness of the reflective layer RLa is 100 nm. The thickness of each of the first coating layer V1 and the second coating layer V2a is 25 nm. The thickness of the second layer L2 is 30 nm.

After the process PR3b, a resist R0 having a shape corresponding to the lower electrodes LE1, LE2, and LE3 is provided on the second layer L2 as shown in FIG. 7B (process PR3c in FIG. 6). Furthermore, first etching for the second layer L2 is performed (process PR3d in FIG. 6). The first etching is, for example, dry etching. The portion of the second layer L2, which is exposed from the resist R0, is removed by the first etching. Accordingly, as shown in FIG. 7C, a mask layer MK having a shape similar to that of the resist R0 is formed.

After the process PR3c, second etching for the first layer L1 is performed (process PR3e in FIG. 6). For example, the first etching includes wet etching performed for the second coating layer V2a, the reflective layer RLa, and the first coating layer V1a in order.

In the wet etching for the second coating layer V2a, the portion of the second coating layer V2a, which is exposed from the resist R0, is removed. Accordingly, as shown in FIG. 7D, the second coating layer V2 is formed. In the wet etching, the width of the second coating layer V2 is slightly reduced relative to the mask layer MK.

In the wet etching for the reflective layer RLa, the portion of the reflective layer RLa, which is exposed from the resist R0, is removed. Accordingly, as shown in FIG. 7E, the reflective layer RL is formed. In addition, in the wet etching, the width of the reflective layer RL is slightly reduced relative to the mask layer MK and the second coating layer V2.

In the wet etching for the first coating layer V1a, the portion of the first coating layer V1a, which is exposed from the resist R0, is removed. Accordingly, as shown in FIG. 7F, the first coating layer V1 is formed. In the wet etching, the width of the first coating layer V1 is slightly reduced relative to the reflective layer RL. In addition, in the wet etching, the second coating layer V2 can also be corroded. Accordingly, in the example of FIG. 7F, the width of the second coating layer V2 is slightly reduced relative to the reflective layer RL.

After the process PR3e, the resist R0 is removed (peeled off) (process PR3f in FIG. 6). Furthermore, annealing treatment is performed for the first coating layer V1 and the second coating layer V2 which are formed of a conductive oxide (process PR3g in FIG. 6). In the annealing treatment, the first coating layer V1 and the second coating layer V2 are crystallized by heating.

The lower electrodes LE1, LE2, and LE3 are completed through the above processes. The end portion of the mask layer MK located on each of the lower electrodes LE1, LE2, and LE3 protrudes relative to the end portion of the lower electrode LE1, LE2, or LE3.

Subsequently, as shown in FIG. 7G, a third layer L3 which covers the lower electrodes LE1, LE2, and LE3 and the mask layer MK is formed (process PR3h in FIG. 6). The third layer L3 is a layer which is processed so as to be the coating layers CR1, CR2, and CR3, and is formed of a positive photosensitive resin. The space located under the mask layer MK which protrudes relative to the first coating layer V1, the reflective layer RL, and the second coating layer V2 is also filled with the third layer L3.

After the process PR3h, the third layer L3 is exposed (process PR3i in FIG. 6). Furthermore, the third layer L3 to which the exposure has been applied is developed (process PR3j in FIG. 6). The portion located under the mask layer MK is not exposed. For this reason, as shown in FIG. 7H, part of the third layer L3 remains near the end portion of the mask layer MK even after the development.

After the process PR3j, third etching for the mask layer MK is performed (process PR3k in FIG. 6). Accordingly, as shown in FIG. 7I, the mask layer MK is removed. The third etching is, for example, wet etching. For the etchant of the wet etching, hydrofluoric acid or buffered hydrofluoric acid (BHF) can be used.

After the process PR3k, the third layer L3 which remains under the mask layer MK is burned (process PR3I in FIG. 6). Accordingly, as shown in FIG. 7J, the coating resin layer CR1 which covers the end portion of the lower electrode LE1 is formed. The coating resin layers CR2 and CR3 are formed in a similar manner. Incidentally, the top surfaces of the coating resin layers CR1, CR2, and CR3 are formed as gently curved surfaces by the burning.

In FIG. 7J, the coating resin layer CR1 covers the whole end portion of the lower electrode LE1 in a manner similar to that of the example of FIG. 4. As another example, the thickness of the coating resin layer CR1 may be reduced by burning. In this case, the coating resin layer CR1 may have a shape which covers part of the end portion of the lower electrode LE1, similarly to the example of FIG. 5.

After the process PR3 described above, as shown in FIG. 8A, the rib layer 5 which covers the lower electrodes LE1, LE2, and LE3 is formed (process PR4 in FIG. 6). Furthermore, the partition 6 having the lower portion 61 and the upper portion 62 is formed on the rib layer 5 (process PR5 in FIG. 6). The lower portion 61 includes the bottom layer 63 and the stem layer 64 as shown in FIG. 3. In addition, the upper portion 62 includes the first top layer 65 and the second top layer 66 as shown in FIG. 3. Incidentally, the structures of the lower electrodes LE1, LE2, and LE3 are simplified in FIG. 8A.

After the formation of the partition 6, as shown in FIG. 8B, the pixel apertures AP1, AP2, and AP3 are formed in the rib layer 5 (process PR6 in FIG. 6). As another example, the pixel apertures AP1, AP2, and AP3 may be formed before the formation of the partition 6.

Subsequently, processes for forming the display elements DE1, DE2, and DE3 are performed (processes PR7, PR8, and PR9 in FIG. 6). In the present embodiment, it is assumed that the display element DE1 is first formed, the display element DE2 is then formed, and the display element DE3 is formed lastly. However, the order of formation of the display elements DE1, DE2, and DE3 is not limited to this example.

To form the display element DE1, first, as shown in FIG. 8C, the stacked film FL1 and the sealing layer SE11 are formed over the entire part of the display area DA and the surrounding area SA. As shown in FIG. 3, the stacked film FL1 includes the organic layer OR1 which is in contact with the lower electrode LE1 through the pixel aperture AP1, the upper electrode UE1 which covers the organic layer OR1, and the cap layer CP1 which covers the upper electrode UE1.

The organic layer OR1, the upper electrode UE1, and the cap layer CP1 are formed by vapor deposition. In addition, the sealing layer SE11 is formed by chemical vapor deposition (CVD). The stacked film FL1 is divided into a plurality of portions by the partition 6 having an overhang shape. The sealing layer SE11 continuously covers the portions into which the stacked film FL1 is divided, and the partition 6.

After the formation of the stacked film FL1 and the sealing layer SE11, a resist R1 is provided on the sealing layer SE11 as shown in FIG. 8C. The resist R1 covers the subpixel SP1 and part of the partition 6 around the subpixel.

After that, as shown in FIG. 8D, the portions of the stacked film FL1 and the sealing layer SE11, which are exposed from the resist R1, are removed by etching using the resist R1 as a mask. Accordingly, the display element DE1 is formed in the subpixel SP1. For example, this etching includes wet etching and dry etching which are performed for the sealing layer SE11, the cap layer CP1, the upper electrode UE1, and the organic layer OR1 in order. After these etching processes, the resist R1 is removed.

The display elements DE2 and DE3 are formed by procedures similar to the procedure of the display element DE1. In other words, to form the display element DE2, the stacked film FL2 and the sealing layer SE12 are formed over the entire part of the display area DA and the surrounding area SA. As shown in FIG. 3, the stacked film FL2 includes the organic layer OR2 which is in contact with the lower electrode LE2 through the pixel aperture AP2, the upper electrode UE2 which covers the organic layer OR2, and the cap layer CP2 which covers the upper electrode UE2. By patterning the stacked film FL2 and the sealing layer SE12, the display element DE2 is formed in the subpixel SP2 as shown in FIG. 8E.

In addition, to form the display element DE3, the stacked film FL3 and the sealing layer SE13 are formed over the entire part of the display area DA and the surrounding area SA. As shown in FIG. 3, the stacked film FL3 includes the organic layer OR3 which is in contact with the lower electrode LE3 through the pixel aperture AP3, the upper electrode UE3 which covers the organic layer OR3, and the cap layer CP3 which covers the upper electrode UE3. By patterning the stacked film FL3 and the sealing layer SE13, the display element DE3 is formed in the subpixel SP3 as shown in FIG. 8F.

After the display elements DE1, DE2, and DE3 are formed, the resin layer RS1, the sealing layer SE2, and the resin layer RS2 shown in FIG. 3 are formed in order (process PR10 in FIG. 6). The display device DSP is completed through the processes.

In the embodiment explained above, the display device DSP comprising the display elements DE1, DE2, and DE3 which are separated from each other for the respective subpixels SP1, SP2, and SP3 and which are individually sealed by the partition 6 having an overhang shape can be obtained.

In addition, the yield and reliability of the display device DSP can be improved by the configuration of the lower electrodes LE1, LE2, and LE3 and the coating resin layers CR1, CR2, and CR3 of the present embodiment. The advantages will be described below.

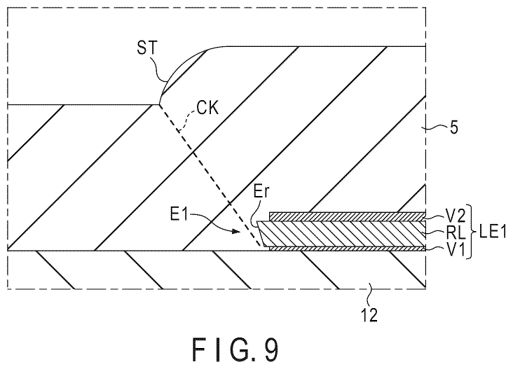

FIG. 9 is a schematic cross-sectional view showing the structure of the vicinity of the end portion E1 of the lower electrode LE according to a comparative example of the present embodiment. In the comparative example of FIG. 9, the coating resin layer CR1 which covers the end portion E1 is not provided.

To increase the reflectance of the lower electrode LE1, the reflective layer RL needs to be formed so as to be thick. In addition, it is difficult to form the end portion Er of the reflective layer RL formed of a metal material such as silver and processed by wet etching so as to have a tapered shape in which the thickness is gradually reduced. Thus, the end portion Er may be formed in a sheer shape substantially parallel to the Z-direction as shown in FIG. 4 or formed in an overhang shape in which the upper end protrudes as shown in FIG. 9.

Thus, in a case where the reflective layer RL is thick, and the shape of the end portion Er is steep, and the rib layer 5 is formed of an inorganic insulating material, a crack CK which extends from the vicinity of the end portion Er to the stepped portion ST of the upper surface of the rib layer 5 may occur. If such a crack CK occurs, a moisture path from the organic insulating layer 12 to the upper surface of the rib layer 5 may be formed. If the moisture of the organic insulating layer 12 reaches the upper surface of the rib layer 5 through the moisture path, the organic layer OR1 provided on the rib layer 5 may be corroded, thereby causing a display failure.

In contrast, in the present embodiment, the coating resin layer CR1 which covers at least part of the end portion E1 is provided. Accordingly, the vicinity of the end portion E1 is planarized, and occurrence of the crack CK in the rib layer 5 is prevented. As a result, penetration of the moisture into the elements provided above the rib layer 5 from the organic insulating layer 12 can be suppressed.

In addition, since occurrence of the crack CK is thus suppressed, the reflectance can be increased by making the reflective layer RL thick. Furthermore, the water resistance can be further increased by making the first coating layer V1 thick and adding an inorganic film under the first coating layer V1.

In addition, in the present embodiment, as shown in FIG. 4, the stepped portion ST of the upper surface of the rib layer 5 generated by the lower electrode LE1 is covered with the lower portion 61. In this case, even if a crack CK occurs, the moisture path through the crack CK can be blocked by the lower portion 61.

In addition, in a case where the mask layer MK for the coating resin layer CR1 is formed by using the resist R0 for the lower electrode LE1 similarly to the manufacturing processes shown in FIG. 7A to FIG. 7J, the displacement in position of the coating resin layer CR1 relative to the lower electrode LE1 can be suppressed.

In this manufacturing process, if the first etching for the second layer L2 (process PR3d in FIG. 7C) is dry etching, the corrosion of the end portion of the mask layer MK is suppressed, and the mask layer MK having the same shape as the resist R0 can be obtained. In addition, if the second etching for the first layer L1 (process PR3e in FIG. 7D to FIG. 7F) is wet etching, the end portions of the first coating layer V1, the reflective layer RL, and the second coating layer V2 are eroded and are likely to retreat relative to the end portion of the mask layer MK. Accordingly, space for formation of the coating resin layer CR1 under the mask layer MK can be desirably formed. Furthermore, if the third etching for the mask layer MK (process PR3k in FIG. 7I) is wet etching using hydrofluoric acid or buffered hydrofluoric acid, damage to the second coating layer V2 and the organic insulating layer 12 which are formed of a conductive oxide can be suppressed.

The advantages obtained from the present embodiment have been described by focusing the lower electrode LE1 and the coating resin layer CR1. However, the same advantages can also be obtained regarding the lower electrodes LE2 and LE3 and the coating resin layers CR2 and CR3.

### Second Embodiment

A second embodiment will be described. The configurations which are not particularly referred to in this embodiment are the same as those of the first embodiment.

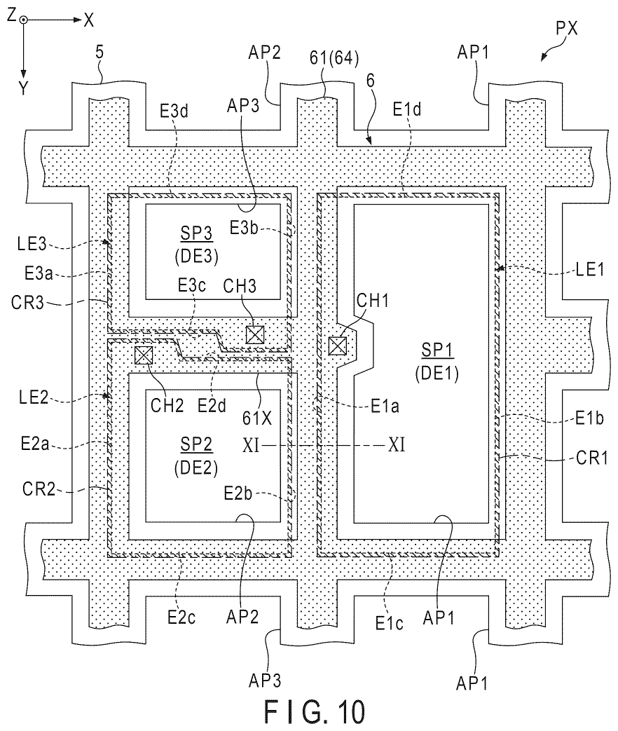

FIG. 10 is a schematic plan view showing an example of a layout of subpixels SP1, SP2, and SP3 according to the present embodiment. As shown in FIG. 10, a lower electrode LE1 has end portions E1a, E1b, E1c, and E1d. A lower electrode LE2 has end portions E2a, E2b, E2c, and E2d. A lower electrode LE3 has end portions E3a, E3b, E3c, and E3d. The end portions E1a, E1b, E2a, E2b, E3a, and E3b extend parallel to a Y-direction. In addition, the end portions E1c, E1d, E2c, E2d, E3c, and E3d extend parallel to an X-direction. All of the end portions are covered with a rib layer 5.

The partition 6 shown in FIG. 10 corresponds to a shape of a lower portion 61, more specifically, a shape of a stem layer 64. In the present embodiment, a part (first end portion) of the end portion of each of the lower electrodes LE1, LE2, and LE3 overlaps with the stem layer 64, and the other part (second end portion) does not overlap with the stem layer 64. In this case, the expression “the end portion of each of the lower electrodes LE1, LE2, and LE3 overlaps with the lower portion 61” means that these end portions are located under the lower portion 61.

More specifically, the end portions E1a and E1c of the lower electrode LE1 overlap with the lower portion 61, and neither the end portion E1b nor the end portion E1d overlaps with the lower portion 61. In addition, the end portions E2a, E2c, and E2d of the lower electrode LE2 overlap with the lower portion 61, and the end portion E2b does not overlap with the lower portion 61. In addition, the end portions E3a and E3c of the lower electrode LE3 overlap with the lower portion 61, and neither the end portion E3b nor the end portion E3d overlaps with the lower portion 61.

For example, when the lower electrodes LE1 and LE2 and the lower portion 61 therebetween are focused, one of the end portions of the lower electrodes LE1 and LE2 overlaps with the lower portion 61, and the other one does not overlap with the lower portion 61. Thus, the relationship in which the lower portion 61 overlaps with the end portion of one of adjacent lower electrodes and does not overlap with the end portion of the other lower electrode is established in a large part of the lower portion 61. However, a part 61X in the lower portion 61, which is located between pixel apertures AP2 and AP3, overlaps with both the end portion E2d of the lower electrode LE2 and the end portion E3c of the lower electrode LE3. Contact holes CH2 and CH3 are provided under the part 61X.

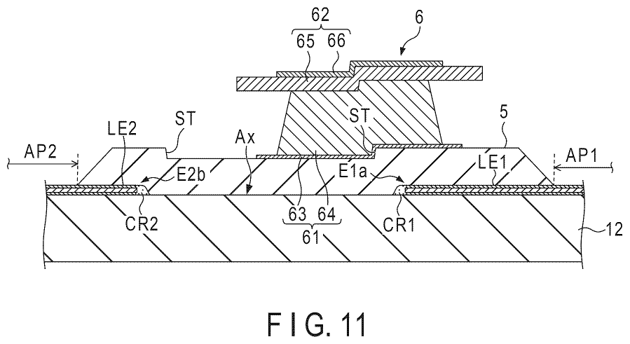

FIG. 11 is the schematic cross-sectional view showing the display device DSP along XI-XI line in FIG. 10. In this figure, similarly to that of FIG. 4, the organic insulating layer 12, the rib layer 5, the partition 6, the lower electrodes LE1 and LE2, and the coating resin layers CR1 and CR2 are shown, and the other elements are omitted.

Similarly to the example of FIG. 4, an area Ax where the organic insulating layer 12 is covered with the rib layer 5 is formed between the coating resin layers CR1 and CR2. In the example of FIG. 11, part of the area Ax overlaps with the partition 6, and the other part does not overlap with the partition 6.

A stepped portion ST generated on the upper surface of the rib layer 5 by an end portion located under the partition 6, such as the end portion Ela, is covered with a bottom layer 63 and the stem layer 64. In contrast, for example, a stepped portion ST generated by an end portion which is not located under the partition 6, such as the end portion E2b, is not covered with the bottom layer 63 or the stem layer 64.

In such a configuration, even if a crack occurs in the rib layer 5 at the stepped portion ST which is not covered with the partition 6, such as the stepped portion ST generated at the end portion E2b of the lower electrode LE2, moisture path caused by the crack can be interrupted by the partition 6. In the present embodiment as well, however, similarly to the first embodiment, the coating resin layers CR1, CR2, and CR3 are provided along the end portions E1, E2, and E3 of the lower electrodes LE1, LE2, and LE3. Therefore, crack of the rib layer 5 caused by the end portions E1, E2, and E3 can be suppressed.

All of the display devices and manufacturing methods thereof that can be implemented by a person of ordinary skill in the art through arbitrary design changes to the display device and manufacturing method thereof disclosed above as each embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device comprising:
an organic insulating layer formed of an organic insulating material;
a lower electrode provided above the organic insulating layer;
a coating resin layer covering at least part of an end portion of the lower electrode;
a rib layer covering the end portion of the lower electrode and the coating resin layer, and including a pixel aperture which overlaps with the lower electrode;
an organic layer covering the lower electrode through the pixel aperture and emitting light in accordance with application of a voltage; and
an upper electrode covering the organic layer.

2. The display device of claim 1, wherein
the coating resin layer surrounds the lower electrode in plan view.

3. The display device of claim 1, wherein
the lower electrode comprises a reflective layer reflecting light emitted from the organic layer, and
the coating resin layer covers at least part of an end portion of the reflective layer.

4. The display device of claim 3, wherein
the lower electrode further comprises a first coating layer located between the organic insulating layer and the reflective layer and formed of a transparent conductive oxide,
the end portion of the reflective layer protrudes relative to an end portion of the first coating layer, and
the coating resin layer fills a gap between the organic insulating layer and the end portion of the reflective layer.

5. The display device of claim 3, wherein
the lower electrode further comprises a second coating layer covering an upper surface of the reflective layer, and
the coating resin layer does not cover an upper surface of the second coating layer.

6. The display device of claim 1, further comprising:
a plurality of subpixels each including the lower electrode, the pixel aperture, the organic layer, the upper electrode, and the coating resin layer, wherein
the coating resin layers of the adjacent subpixels are separated.

7. The display device of claim 6, wherein
the organic insulating layer is covered with the rib layer in an area between the adjacent coating resin layers.

8. The display device of claim 7, further comprising:
a partition including a lower portion provided above the rib layer, and an upper portion having an end portion which protrudes from a side surface of the lower portion.

9. The display device of claim 8, wherein
the plurality of subpixels include a first subpixel and a second subpixel adjacent via the partition, and
both an end portion of the lower electrode of the first subpixel and an end portion of the lower electrode of the second subpixel overlap with the partition in plan view.

10. The display device of claim 8, wherein
the plurality of subpixels include a first subpixel and a second subpixel adjacent via the partition, and
one of an end portion of the lower electrode of the first subpixel and an end portion of the lower electrode of the second subpixel overlaps with the partition and the other does not overlap with the partition, in plan view.

11. The display device of claim 1, wherein
a width of the coating resin layer is greater than or equal to 0.2 μm.

12. The display device of claim 1, wherein
the coating resin layer is formed of a positive photosensitive resin.

13. A display device manufacturing method comprising:
forming an organic insulating layer of an organic insulating material;
forming a lower electrode and a coating resin layer covering at least part of an end portion of the lower electrode, above the organic insulating layer;
forming a rib layer covering the end portion of the lower electrode and the coating resin layer, and including a pixel aperture which overlaps with the lower electrode;
forming an organic layer covering the lower electrode through the pixel aperture and emitting light in accordance with application of a voltage; and
forming an upper electrode covering the organic layer.

14. The display device manufacturing method of claim 13, wherein
the forming the lower electrode and the coating resin layer includes:
forming a first layer of a material of the lower electrode above the organic insulating layer;
forming a second layer having light-shielding properties above the first layer;
providing a resist on the second layer;
forming a mask layer by removing a portion of the second layer, which is exposed from the resist, by first etching;
forming the lower electrode having a width smaller than the mask layer by removing a portion of the first layer, which is exposed from the resist, by second etching;
removing the resist;
forming a third layer of a positive photosensitive resin, which covers the lower electrode and the mask layer;
exposing the third layer;
developing the exposed third layer; and
removing the mask layer by third etching, and
the coating resin layer is formed by the third layer remaining under an end portion of the mask layer, which protrudes from the end portion of the lower electrode in the development.

15. The display device manufacturing method of claim 14, wherein
the first etching is dry etching.

16. The display device manufacturing method of claim 15, wherein
the third etching is wet etching.

17. The display device manufacturing method of claim 16, wherein
the second layer is formed of titanium, and
an etchant in the third etching contains hydrofluoric acid or buffered hydrofluoric acid.

18. The display device manufacturing method of claim 14, wherein
the second etching is wet etching.

19. The display device manufacturing method of claim 13, further comprising:
forming a partition including a lower portion provided above the rib layer and an upper portion having an end portion which protrudes from a side surface of the lower portion, before forming the organic layer and the upper electrode.

20. The display device manufacturing method of claim 19, wherein
the partition is formed to overlap with at least part of an end portion of the lower electrode, in plan view.
